(19) United States
(12) Patent Application Publication
(10) Pub. No.: US 2025/0391446 A1
(43) Pub. Date: Dec. 25, 2025

(54) VOLTAGE MANAGEMENT CIRCUIT

(71) Applicant: SILVACO Inc., Santa Clara, CA (US)

(72) Inventor: Eitan Zmora, Mevaseret-Zion (IL)

(73) Assignee: SILVACO Inc., Santa Clara, CA (US)

(21) Appl. No.: 18/878,525

(22) PCT Filed: Jun. 21, 2023
(86) PCT No.: PCT/US2023/025887

§ 371 Date: Dec. 23, 2024

Related U.S. Application Data
(60) Provisional application No. 63/354,575, filed on Jun. 22, 2022.

(51) Int. Cl. G11C 5/14; G11C 11/419

(52) U.S. Cl. CPC G11C 5/145; G11C 11/419

(57) ABSTRACT

Technologies and implementations for a voltage management circuit. The voltage management circuit may be configured to facilitate management of behavior of electronic devices including management of process corners associated with semiconductor integrated circuit devices. The technologies and implementations may facilitate a controlled amplitude for a signal that may be configured to push a negative ground capacitor. The amplitude may decrease as a process corner becomes faster.

### CROSS-REFERENCE TO RELATED APPLICATIONS

This application claims benefit of priority to U.S. Provisional Patent Application Ser. No. 63/354,575, filed Jun. 22, 2022, titled VOLTAGE MANAGEMENT CIRCUIT, which is incorporated herein by reference in its entirety for all purposes.

### BACKGROUND

Unless otherwise indicated herein, the approaches described in this section are not prior art to the claims in this application and are not admitted to be prior art by inclusion in this section.

Semiconductors may be considered to be ubiquitous in many technology areas. For example, semiconductors may be included in smartphones, computers, vehicles, televisions, and so forth. The manufacturing of the semiconductors, which may be included in so many devices, may be considered to be complicated and costly. Part of the complication may include semiconductor processing, where the semiconductors may be manufactured. The manufacturing of semiconductors may include a wide variety of technologies. One example of technology that may be involved with semiconductor processing may include determining a behavioral characteristic of semiconductors. For example, how the semiconductor may perform under various conditions.

Determining how a semiconductor may perform under various conditions may involve determining behaviors as semiconductor process corners. For example, semiconductor process corners may refer to specific variations or extremes in process parameters, which may be used during the fabrication of integrated circuits. The process corners may facilitate accounting for process uncertainties and may facilitate understanding of the performance and reliability of semiconductor devices.

In semiconductor manufacturing, a wide range of factors may influence the behavior and characteristics of a device, including temperature, voltage, process variations, and material properties. The process corners may include the various combinations of these factors to help facilitate the evaluation of the performance of the device under various operating conditions.

Each process corner may represent a specific set of process parameters and design rules that facilitate to define a best-case, a worst-case, and a typical case scenarios for the manufacturing process. For example, process corners may be defined based on factors such as, but not limited to, a minimum and a maximum values of supply voltage, temperature, and/or manufacturing variations in various dimensions.

The process corners may help to facilitate ensuring that the manufactured devices may meet various performance specifications and withstand variations and uncertainties, which may be encountered in real-world operating conditions. The process corners may play a prominent role in design verification, device characterization, and/or reliability testing.

Evaluation of robustness and/or tolerance of a semiconductor design and its various design variations may be simulated and/or tested under various process corners to facilitate identification of potential issues and/or performance limitations of the semiconductor design. The evaluation may help to facilitate providing of information to the semiconductor designer to make informed decisions related to the semiconductor device architecture, semiconductor circuit design, and/or its performance.

Accordingly, semiconductor process corners may be considered an integral part of semiconductor design, semiconductor manufacturing process, semiconductor analysis, and/or optimization of semiconductor integrated circuit design applicable to real-world conditions. As a result, management and/or control of process corners may contribute to the development of reliable and/or high-performance semiconductor devices across a wide range of applications, from consumer electronics to automotive systems and advanced computing.

All subject matter discussed in this section of this document is not necessarily prior art and may not be presumed to be prior art simply because it is presented in this section. Plus, any reference to any prior art in this description is not and should not be taken as an acknowledgement or any form of suggestion that such prior art forms parts of the common general knowledge in any art in any country. Along these lines, any recognition of problems in the prior art are discussed in this section or associated with such subject matter should not be treated as prior art, unless expressly stated to be prior art. Rather, the discussion of any subject matter in this section should be treated as part of the approach taken towards the particular problem by the inventor(s). This approach in and of itself may also be inventive. Accordingly, the foregoing summary is illustrative only and not intended to be in any way limiting. In addition to the illustrative aspects, embodiments, and features described above, further aspects, embodiments, and features will become apparent by reference to the drawings and the following detailed description.

### SUMMARY

Described herein are various illustrative methods, systems, and apparatus for facilitating management of process corners.

Some example systems may include an integrated circuit including an electronic device, where the electronic device may have one or more transistors. Some example systems may include a voltage management circuit, where the voltage management circuit may be electrically coupled to the electronic device and have one or more transistors configured to manage a behavior of a voltage of the electronic device.

Some example methods may include electrically coupling a port out of a first integrated circuit cell to a port in of a second integrated circuit cell. Some example methods may include electrically coupling a port out of the second integrated circuit cell to a port in of a third integrated circuit cell, where the first integrated circuit cell may be a clamp high circuit, the second integrated circuit cell may be a clamp low circuit, and the third integrated circuit cell may be a clamp high circuit. Some example methods may include electrically coupling a port out of the third integrated circuit cell to an electronic device.

The foregoing summary is illustrative only and not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

Subject matter is particularly pointed out and distinctly claimed in the concluding portion of the specification. The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 illustrates examples of some components as to described with respect to various embodiments.

FIGS. 2A-2C illustrate a component of a voltage management circuit in accordance with some embodiments.

FIGS. 3A-3C illustrate a component of a voltage management circuit in accordance with some embodiments.

FIGS. 4A and 4B illustrate a voltage management circuit in accordance with various embodiments.

FIG. 5 illustrates an example device, with which some embodiments may be utilized.

FIG. 6 illustrates an example utilization of a voltage management circuit in accordance with various embodiments.

FIG. 7 illustrates an example device, with which some embodiments may be utilized.

FIG. 8 illustrates an example device, with which some embodiments may be utilized.

FIG. 9 illustrates an example utilization of a voltage management circuit in accordance with various embodiments.

FIG. 10 illustrates utilization of a voltage management circuit in accordance with some additional embodiments.

FIG. 11 illustrates a block diagram of system for facilitating management of process corners in accordance with various embodiments.

FIG. 12 illustrates an operation flow of the various embodiments disclosed herein.

FIG. 13 illustrates a computer program product in accordance with various embodiments.

FIG. 14 illustrates an example computer device.

FIGS. 15A-15C illustrate wave forms associated with some embodiments.

FIGS. 16A-16B illustrate some circuit behavior associated with some embodiments.

### DETAILED DESCRIPTION

The following description sets forth various examples along with specific details to provide a thorough understanding of claimed subject matter. It will be understood by those skilled in the art after review and understanding of the present disclosure, however, that claimed subject matter may be practiced without some or more of the specific details disclosed herein. Further, in some circumstances, well-known methods, procedures, systems, components and/or circuits have not been described in detail in order to avoid unnecessarily obscuring claimed subject matter.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

In circuit design, a reference column may utilize a negative ground. Utilization of a negative ground may facilitate improved matching of functional columns. For example, in fast corners, a reference column may be too fast, which may lead to risk of margins with no apparent need. Speed may matter in slow corners. This disclosure is drawn, inter alia, to methods, apparatus, and circuit systems to facilitate a controlled amplitude for a signal that may be configured to push a negative ground capacitor. The amplitude may decrease as a process corner becomes faster.

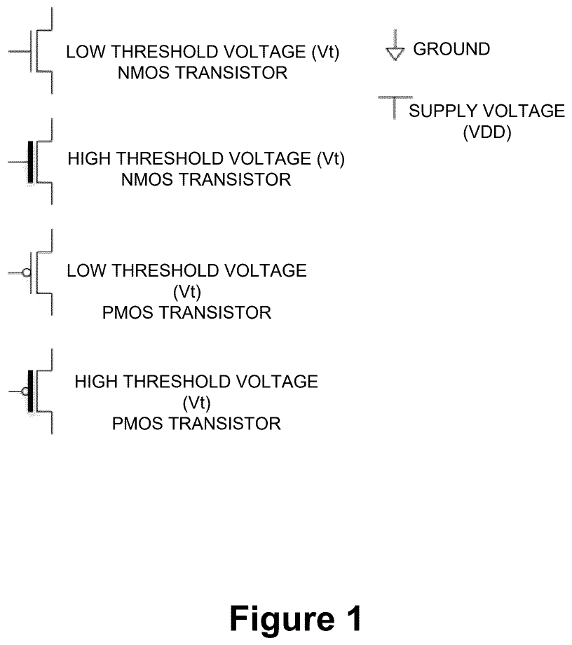

Turning now to FIG. 1, FIG. 1 illustrates examples of some components, which may be utilized to describe the various embodiments as disclosed herein. It should be appreciated that the example components are but just some examples, and accordingly, the claimed subject matter may be include substitute components and/or similar components. The claimed subject matter is not limited in these respects.

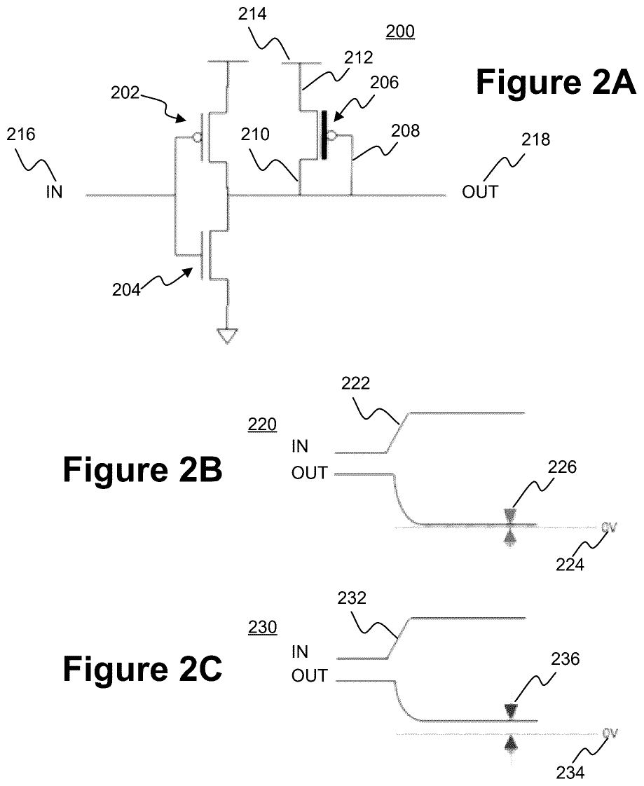

FIGS. 2A-2C illustrate a component of a voltage management circuit in accordance with some embodiments. In FIG. 2, a first component 200 may include a first transistor 202, a second transistor 204, and a third transistor 206 configured as shown.

In the non-limiting example shown in FIG. 2A of the first component 200, the first transistor 202 and the third transistor 206 may be PMOS transistors. In another example, the second transistor 204 may be an NMOS transistor. In an example, the first transistor 202 may be a low threshold voltage PMOS transistor, the third transistor 206 may be a high threshold voltage PMOS transistor, and the second transistor 204 may be a low threshold voltage NMOS transistor. Shown in FIG. 2A, the first component 200 may be configured to be a clamp circuit such as, but not limited to, a clamp high circuit.

Continuing with the non-limiting example of the first component 200 configured to be a clamp circuit, the first transistor 202 and the second transistor 204 may be configured to operate as an inverter circuit such as, but not limited to, a low voltage inverter circuit. The third transistor 206 may have its gate 208 electrically coupled with its drain 210, while its source 212 may be electrically coupled with a positive voltage (e.g., VDD 214). Accordingly, the third transistor 206 may be referred to as a clamp. In this non-limiting configuration, when IN 216 is low, OUT 218 may be substantially equal to high. When IN 216 is high, net OUT 218 may be pulled down by the second transistor 204, while the third transistor 206 may operate as a clamp due to its gate 208 being electrically coupled with its drain 210. Additionally, the level of OUT 218 may be such that a current (e.g., Ids) of the second transistor 204 may be substantially similar to a current (e.g., Ids) of the third transistor 206. As a result, when IN 216 is high, the level of OUT 218 may be based, at least in part, on Process, Voltage, and Temperature (PVT).

Turning now to FIG. 2B, FIG. 2B illustrates operational information of the first component 200 of a voltage management circuit in accordance with various embodiments. In FIG. 2B, the first component 200 may be utilized for slow process conditions (e.g., a slow corner 220). As shown in FIG. 2B, at a slow corner 220 (e.g., slow process, low voltage, and low temperature), a voltage 222 applied to IN 216 may be relatively high at the third transistor 206 as may be compared with respect the level of positive voltage (e.g., VDD). As a result, a current (e.g., Ids) of the third transistor 206 may be relatively low as compared to a current of the second transistor 204 (e.g., Ids). The level of OUT 218 may be relatively close to 0 volts 224 when the current of the second transistor 204 and the third transistor 206 are substantially equal as shown by a slow corner difference 226.

FIG. 2C illustrates operational information of the first component 200 of a voltage management circuit in accordance with various embodiments. In FIG. 2C, the first component 200 may be utilized for fast process conditions (e.g., a fast corner 230). As shown in FIG. 2C, at a fast corner 230 (e.g., fast process, high voltage, and high temperature), a voltage 232 applied to IN 216 may be relatively low at the third transistor 206 as may be compared with respect the level of positive voltage (e.g., VDD). As a result, a current (e.g., Ids) of the third transistor 206 may be relatively high as compared to a current of the second transistor 204 (e.g., Ids). The level of OUT 218 may be relatively farther away from 0 volts 234 when the current of the second transistor 204 and the third transistor 206 are substantially equal as shown by a fast corner difference 236.

In some embodiments, the slow corner difference 226 and/or the fast corner difference 236 may be affected by selection of transistor sizing. Accordingly, tuning of the behavior of the first component 200 at slow corners and/or fast corners may be managed.

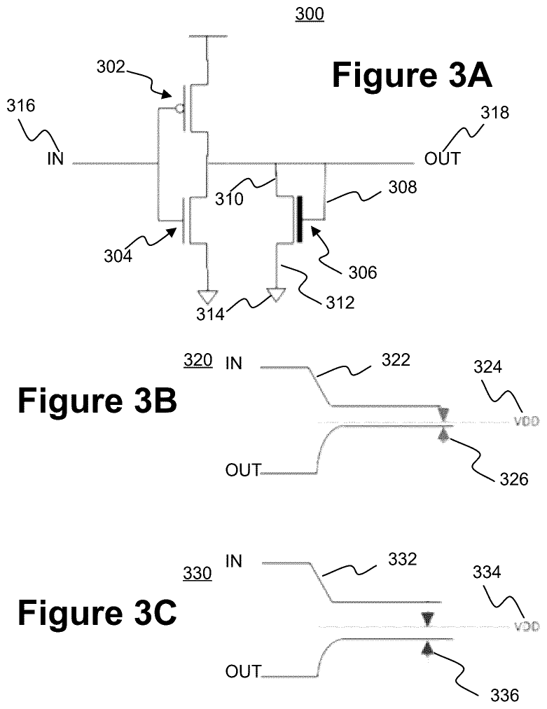

FIGS. 3A-3C illustrate a component of a voltage management circuit in accordance with some embodiments. In FIG. 3, a second component 300 may include a first transistor 302, a second transistor 304, and a third transistor 306 configured as shown.

In the non-limiting example shown in FIG. 3A of the second component 300, the second transistor 302 and the third transistor 306 may be NMOS transistors. In another example, the first transistor 304 may be a PMOS transistor. In an example, the second transistor 304 may be a low threshold voltage NMOS transistor, the third transistor 306 may be a high threshold voltage NMOS transistor, and the first transistor 302 may be a low threshold voltage PMOS transistor. Shown in FIG. 3A, the second component 300 may be configured to be a clamp circuit such as, but not limited to, a clamp low circuit.

Continuing with the non-limiting example of the second component 300 configured to be a clamp circuit, the first transistor 302 and the second transistor 304 may be configured to operate as an inverter circuit such as, but not limited to, a low voltage inverter circuit. The third transistor 306 may have its gate 308 electrically coupled with its drain 310, while its source 312 may be electrically coupled with a ground 314. Accordingly, the third transistor 206 may be referred to as a clamp. In this non-limiting configuration, when IN 316 is high, OUT 318 may be substantially equal to low. When IN 316 is net, net OUT 216 may be pulled up by the first transistor 302, while the third transistor 306 may operate as a clamp due to its gate 308 being electrically coupled with its drain 310. Additionally, the level of OUT 316 may be such that a current (e.g., Ids) of the first transistor 304 may be substantially similar to a current (e.g., Ids) of the third transistor 306. As a result, when IN 316 is high, the level of OUT 318 may be based, at least in part, on Process, Voltage, and Temperature (PVT).

Turning now to FIG. 3B, FIG. 3B illustrates operational information of the second component 300 of a voltage management circuit in accordance with various embodiments. In FIG. 3B, the second component 300 may be utilized for slow process conditions (e.g., a slow corner 320). As shown in FIG. 3B, at a slow corner 320 (e.g., slow process, low voltage, and low temperature), a voltage 322 applied to IN 316 may be relatively high at the third transistor 306 as may be compared with respect the level of positive voltage (e.g., VDD). As a result, a current (e.g., Ids) of the third transistor 306 may be relatively low as compared to a current of the first transistor 304 (e.g., Ids). The level of OUT 318 may be relatively close to VDD 324 when the current of the first transistor 302 and the third transistor 306 are substantially equal as shown by a slow corner difference 326.

FIG. 3C illustrates operational information of the second component 300 of a voltage management circuit in accordance with various embodiments. In FIG. 3C, the second component 300 may be utilized for fast process conditions (e.g., a fast corner 330). As shown in FIG. 3C, at a fast corner 330 (e.g., fast process, high voltage, and high temperature), a voltage 332 applied to IN 316 may be relatively low at the third transistor 306 as may be compared with respect the level of positive voltage (e.g., VDD). As a result, a current (e.g., Ids) of the third transistor 306 may be relatively high as compared to a current of the first transistor 302 (e.g., Ids). The level of OUT 318 may be relatively lower away from VDD 334 when the current of the first transistor 304 and the third transistor 306 are substantially equal as shown by a fast corner difference 336.

In some embodiments, the slow corner difference 326 and/or the fast corner difference 336 may be affected by selection of transistor sizing. Accordingly, tuning of the behavior of the second component 300 at slow corners and/or fast corners may be managed.

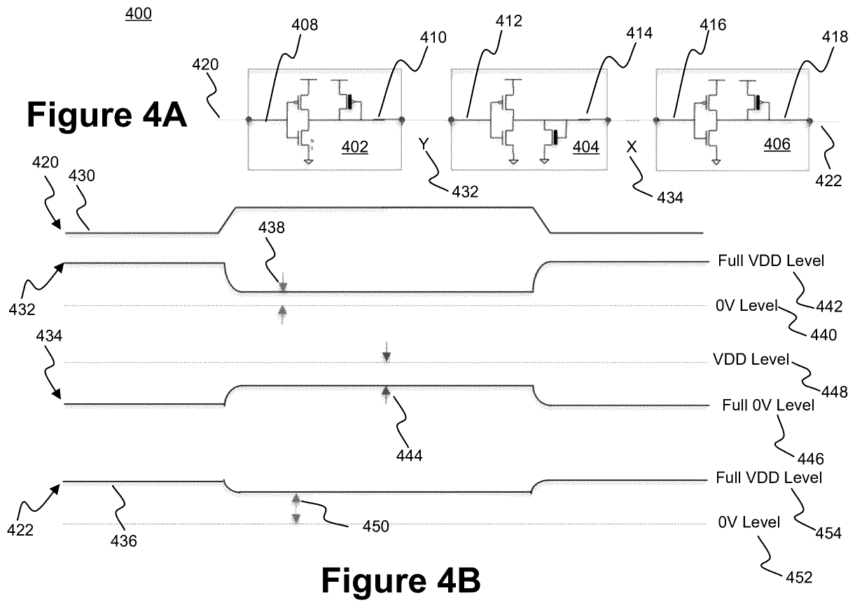

FIGS. 4A and 4B illustrate a voltage management circuit in accordance with various embodiments. In FIG. 4A, a voltage management circuit 400 may include a first component 402, a second component 404, a third component 406. In the one embodiment shown in FIG. 4, the first component 402, the second component 404, and the third component 406 may be electrically coupled in series. The first component 402 may be similar to the first component 200 of FIG. 2A, the second component 404 may be similar to the second component 300 of FIG. 3A, and the third component may be a second iteration of the first component 200 of FIG. 2A. For example, the voltage management circuit 400 may include a clamp high (e.g., the first component 200), a clamp low (e.g., the second component 300), and a second clamp high (e.g., the first component 200) electrically coupled with each other. In one example, the components 402, 404, and 406 (hereon out, CLAMP HIGH 402, CLAMP LOW 404, and CLAMP HIGH 406) may be electrically coupled in series forming a “Chain” like arrangement (hereon out, CHAIN 400).

As shown in FIG. 4, CLAMP HIGH 402 may include a port IN 408 and a port OUT 410. The CLAMP LOW 404 may include a port IN 412 and a port OUT 414. The CLAMP HIGH 406 may include a port IN 416 and a port OUT 418. The one embodiment of the CHAIN 400 may include a CHAIN IN 420 and a CHAIN OUT 422.

Continuing with the embodiment of FIG. 4, the port OUT 410 of CLAMP HIGH 402 may be electrically coupled to the port IN 412 of CLAMP LOW 404. The port OUT 414 of CLAMP LOW 404 may be electrically coupled with a port IN 416 of CLAMP HIGH 406.

The one example arrangement shown in FIG. 4 may have the cells (i.e., CLAMP HIGH 402, CLAMP LOW 404, and CLAMP HIGH 406) of the CHAIN 400 in an alternating arrangement. However, in some examples, the cells may have a different arrangement such as, but not limited to, more than one similar cells electrically coupled to each other. Additionally, in some examples, the first cell in the CHAIN 400 may be CLAMP LOW 404. Further, the number of cells may vary, which may be implementation dependent and may be base, at least in part, on desired electrical signal behavior. Accordingly, the claimed subject matter is not limited in these respects.

Turning now to FIG. 4B, FIG. 4B illustrates operational information of the CHAIN 400 in accordance with various embodiments. In FIG. 4B, a digital signal input may be applied to the CHAIN IN 420, which may be electrically coupled with the port IN 408 of the CLAMP HIGH 402. In an example, where the digital signal input may be equivalent to a logic 0, the CHAIN 400 may behave substantially similar to a series of inverters. The CHAIN OUT 422 may be a digital signal, where in the one embodiment shown in FIG. 4A, the arrangement of the cells (i.e., the CLAMP HIGH 402, the CLAMP LOW 404, the CLAMP HIGH 406), the digital signal at the CHAIN OUT 422 may be equivalent to a logic 1.

In another example, where the digital signal input may be equivalent to a logic 1 at CHAIN IN 420, the transistors in the CHAIN 400 may behave similar to clamping circuits as described above. That is, when the CHAIN IN 420 is a logic 1, the transistors in the cells (i.e., the CLAMP HIGH 402, the CLAMP LOW 404, the CLAM HIGH 406) may be active when the CHAIN IN 420 is a logic 1. Accordingly, the output level at the port OUTs 410, 414, and 418 may be reduced relative to the logic level that an inverter may have reached. This reduced level effect may be cumulative (i.e., from chain part to chain part, the voltage difference from the digital logic level may increase) as shown in FIG. 4B.

In FIG. 4B, an input voltage 430 may be shown as being provided at CHAIN IN 420. Additionally, an electrical coupling of the CLAMP HIGH 402 and CLAMP LOW 404 (i.e., between the port OUT 410 and the port IN 412) may be labeled as Y 432. An electrical coupling of the CLAMP LOW 404 and the CLAMP HIGH 406 (i.e., between the port OUT 414 and the port IN 416) may be labeled as X 434. Further, an output voltage 436 may be shown as being at the CHAIN OUT 420 (i.e., port OUT 418 of CLAMP HIGH 406).

As shown in FIG. 4B, the reduced level effect may be illustrated as a first voltage difference 438, which may be at Y 432. The first voltage difference 438 may be the voltage difference between a 0V voltage level 440 and a Full VDD voltage level 442. In FIG. 4B, a second voltage difference 444 may be illustrated, which may be at X 434. The second voltage difference 444 may be the voltage difference between a Full 0V voltage level 446 and a VDD voltage level 448. A third voltage difference 450 may be at the CHAIN OUT 420. The third voltage difference 450 may be the voltage difference between a 0V voltage level 452 and a Full VDD voltage level 454. As shown in FIG. 4B, the first voltage difference 438 may be relatively small (i.e., close to the 0V voltage level 440), the second voltage difference 444 may be relatively larger (i.e., farther away from the VDD voltage level 448), and the third voltage difference 450 may be relatively even larger (i.e., even farther away from 0V voltage level 452). Accordingly, the second voltage difference 444 may be larger than the first voltage difference 438, and the third voltage difference 450 may be larger than the second voltage difference 444 resulting in a cumulative reduced level effect (i.e., from chain part to chain part, the voltage difference from the digital logic level may increase). As a result, management of voltage may be facilitated by various embodiments disclosed herein.

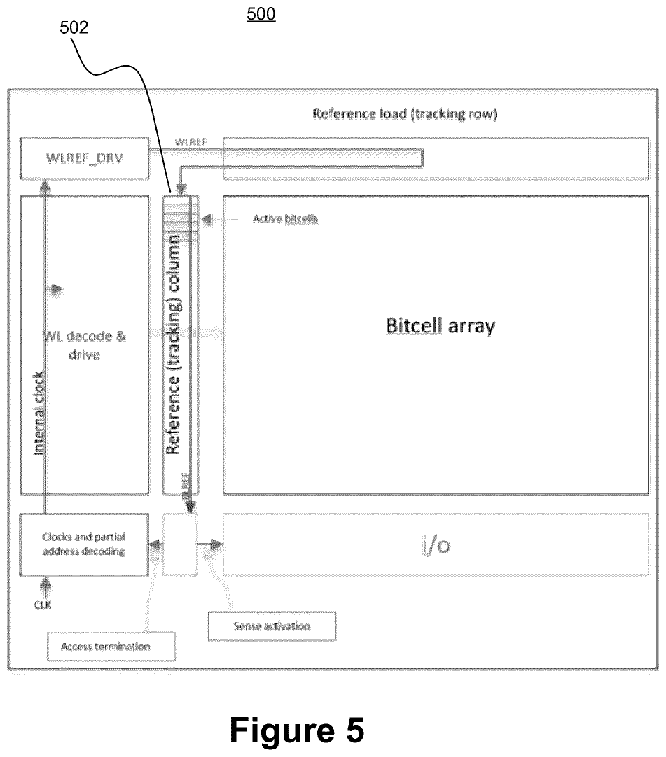

FIG. 5 illustrates an example device, with which some embodiments may be utilized. Shown in FIG. 5 may be a block diagram of a memory device, which may be of a type of a static random-access memory (SRAM 500). As show in FIG. 5, the SRAM 500 may include various components. The SRAM 500 may be an embedded memory, which may have a self-timing circuit. The self-timing circuit may be configured to be triggered by an external clock rise. The self-timing circuit may be implemented as a reference column 502, which may be known as a dummy column, a replica column, and/or a tracking column. One of ordinary skill in the relevant art may be familiar with the self-timing circuit implemented as the reference column 502 in SRAM 500. For example, the self-timing circuit may be configured to operate to indicate when an access (e.g., read and/or write) may end (e.g., when read and/or write margin has been achieved). Accordingly, when a dedicated column is being read, the read operation may start at an external clock rise, when the read operation is complete.

Prior to utilization of the claimed subject matter, a brief description of the operation of the SRAM 500 may be described. In FIG. 5, the reference column 502 may be described as a circuit in the SRAM 500. In the example SRAM 500, a CLK input (blue arrow on bottom left) may be configured to trigger a read and/or write access according to the state of other control inputs resulting in activation of an Internal clock. A cell WLREF DRV may be configured to drive a signal WLREF to 1. The reference column 502 may be in a state of being read (i.e., a reference column bitline, BLREF may be discharged (e.g., red, crossing the reference column). Access termination may have been activated, and in case of read access, a sense-amp may have been activated as well. Access termination may correspond to a reset of substantially all internal clocks, a precharge of bitlines, and/or substantially all other operations to facilitate returning to an idle state for the SRAM 500. The idle state may facilitate the SRAM 500 being prepared for a subsequent access. Additionally, the SRAM 500 may include a read assist method, which may be known as a Negative Ground. If the SRAM 500 includes the read assist method of a Negative Ground, the reference column may also include a Negative Ground to facilitate improved tracking of memory timing.

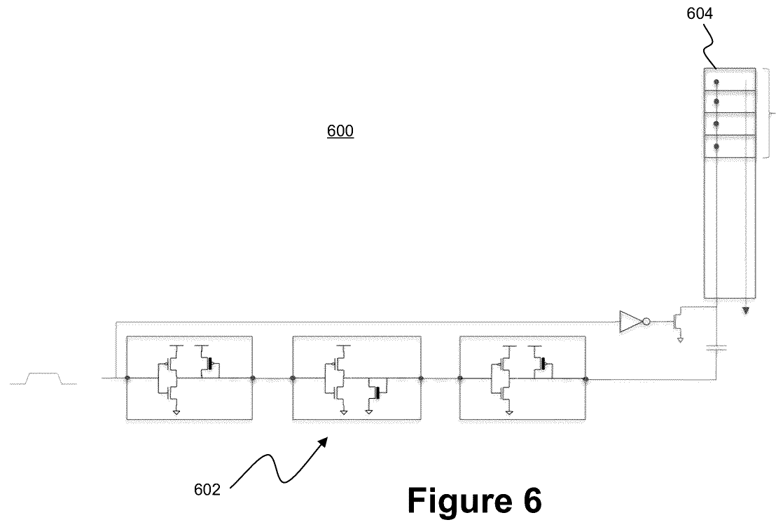

FIG. 6 illustrates an example utilization of a voltage management circuit in accordance with various embodiments. In FIG. 6, a circuit arrangement 600 may include a voltage management circuit 602, which may be electrically coupled with a reference column 604. The voltage management circuit 602 may be similar to the voltage management circuit 400 shown in FIG. 4. The reference column 604 may be similar to the Reference (tracking) column shown in FIG. 5. In FIG. 6, in order to facilitate tracking of the ground of the bitcells array, the Reference column ground may be pulled to a negative voltage level. The negative voltage level may facilitate operation at a low voltage, a slow process, and/or at low temperature (i.e., a slow corner). However, the negative voltage level may cause the reference column to be substantially fast at a fast corner (i.e., a high voltage, a slow process, and/or at high temperature), which may result in read and/or write margins to be insufficient for proper operation of the SRAM.

Utilization of the voltage management circuit 602 with the reference column as shown may facilitate generation of a full swing transition at a net CHAIN OUT for a slow corner. Conversely, utilization of the voltage management circuit 602 with the reference column 604 as shown may facilitate a partial swing at the net CHAIN OUT for a fast corner. Facilitating the partial swing may result in the read and/or write margins to be sufficient for the proper operation of the SRAM at the fast corner, where speed may not be needed.

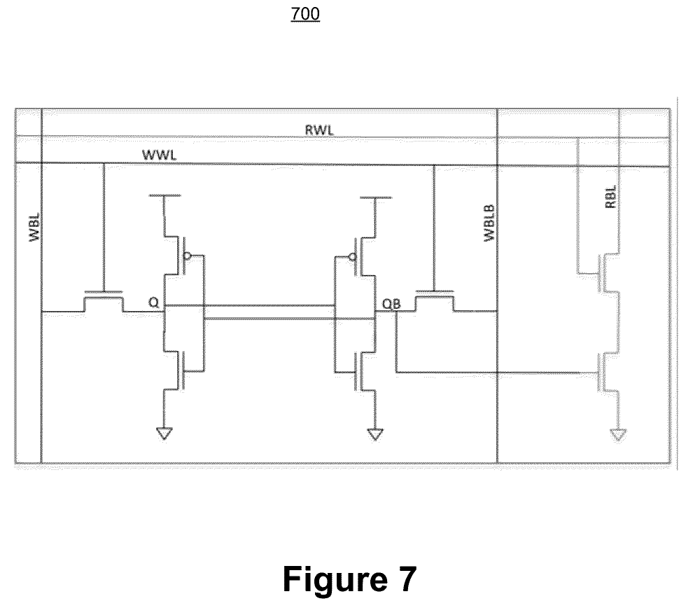

FIG. 7 illustrates an example device, with which some embodiments may be utilized. Shown in FIG. 7 may be a block diagram of a portion of a memory device, which may be of a type of a static random-access memory (SRAM). As show in FIG. 7, the portion may be a schematic of a bitcell circuit (hereon out, bitcell 700) having various components. Additionally, the bitcell 700 may be included in an SRAM type memory device having 8 transistor bitcell (8T), which may be also referred to as 6 transistor+2 transistor bitcell (6T+2T) type memory. The 6T part may be of a known topology, which may be utilized for writing and storing cell data (e.g., 0 or 1). In FIG. 7, a read part of the bitcell 700 may be shown in green.

Prior to utilization of the claimed subject matter, a brief description of the operation of the bitcell 700 may be provided. In an idle state, the Read Word Line (RWL) may be in a state of 0, and the Read Bitline (RBL) may be precharged in advance to a voltage level of circuit supply (e.g., VDD voltage level). A precharge circuit (not shown) may be utilized to precharge the RBL. During a read operation, the precharge circuit may be electrically disconnected, and the RBL may be held at substantially VDD voltage level due to presence of a parasitic capacitance. After the precharge circuit is disconnected, the RWL may change state to 1. If a cell storage net QB is at a state 0, the RBL may remain at a state level 1 as well. A voltage drop due to voltage leakage may be negligible. If the cell storage net QB is at a state level 1, the RBL may be discharged. The discharging of the RBL may be affected by various factors. In one example, a full discharge to a voltage level, which may be recognized as a logic level0 may take too long. In another example, a partial discharge may require utilization of a sense amplifier to facilitate identification of the partial discharge as a logic level 0.

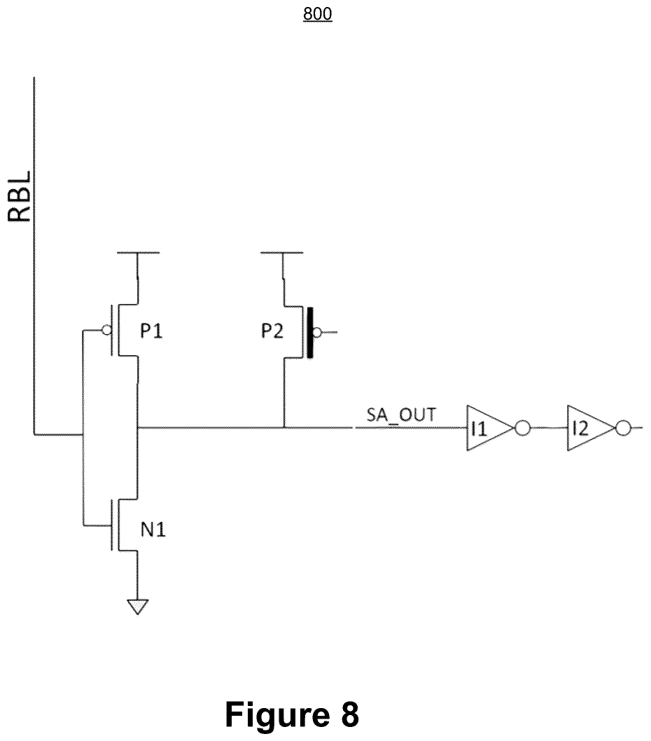

FIG. 8 illustrates an example device, with which some embodiments may be utilized. In FIG. 8, a simplified block diagram of a sense amplifier (sense amp 800) may be shown to include various components. The sense amp 800 may be of a single ended type, which may be utilized in memory devices. Some example memory devices may be configured to include a single bitline per column as compared to memory devices configured to include two bitlines (e.g., 6T SRAM). Here again, prior to utilization of the claimed subject matter, a brief description of the operation of the sense amp 800 may be provided. In the one example of the sense amp 800 shown in FIG. 8, a Read Bit Line (RBL) may be pre-charged to a VDD voltage level (now shown). A selected bitcell may discharge the RBL in accordance with a bitcell logic state.

In FIG. 8, the sense amp 800 may include a low threshold voltage PMOS transistor (P1) and a low threshold voltage NMOS transistor (N1), which may be arranged to operate as an inverter. A high threshold voltage PMOS transistor (P2) may be electrically coupled with the P1 and N1, where the P2 may affect the operation of the inverter (e.g., affect the trip point of the inverter). It should be appreciated that selection of class of threshold voltage (Vt) and sizes of the transistors (P1, N1, and P2) may set a trip point, which may be higher than that of the inverter.

Shown in FIG. 8, the sense amp 800 may be electrically coupled with two inverters (I1 and I2). The two inverters I1 and I2 may be electrically coupled at a sense amp out (SA OUT). The two inverters I1 and I2 may facilitate buffering because the SA OUT low level voltage may be slightly higher than 0 volts (0V). It should be appreciated that different PVTs may affect the trip point, which may cause the trip points to be different. In some examples, the trip point variance over PVT may be relatively too wide. In one example, at some PVTs, the trip point may be too low, which may lead to a too slow of a read operation. In another example, at some PVTs, the trip point may be too high, which considering mismatch variance, may lead to a wrong result at the sense amp 800 (e.g., at SA OUT).

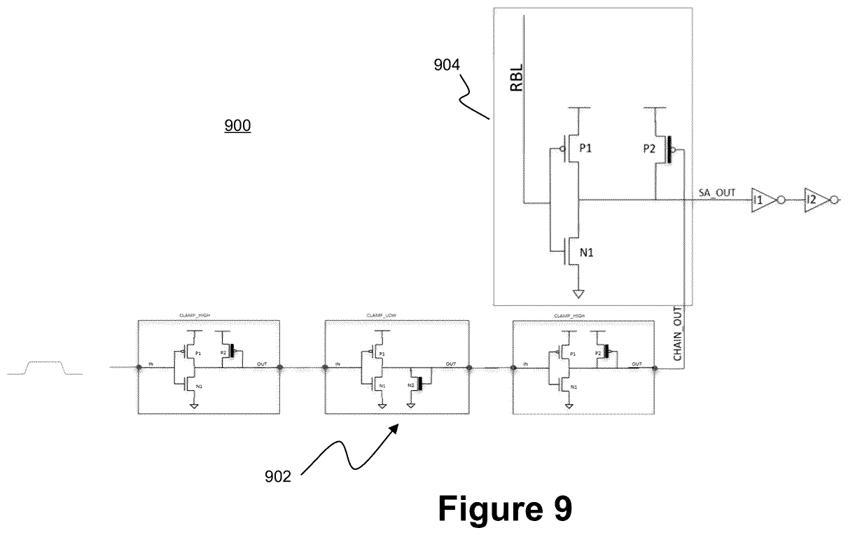

FIG. 9 illustrates an example utilization of a voltage management circuit in accordance with various embodiments. In FIG. 9, a circuit arrangement 900 may include a voltage management circuit 902, which may be electrically coupled with a sense amp 904. The voltage management circuit 902 may be to the voltage management circuit 400 shown in FIG. 4. The sense amp 904 may be similar to the sense amp 800 shown in FIG. 8. In FIG. 9, a CHAIN OUT of the voltage management circuit 902 may be electrically coupled with a gate of a high threshold voltage PMOS transistor (P2) of the sense amp 904.

In the circuit arrangement 900, a low threshold voltage PMOS transistor of a CLAMP LOW in the voltage management circuit 902 may have substantially the same threshold voltage (Vt) of P2 of the sense amp 904. In operation, a positive pulse may be provided at CHAIN IN of the voltage management circuit 902 for aa low level at the CHAIN OUT. The positive pulse may be a signal that may remain at a logic state 1 for a predetermined time when the high threshold voltage PMOS transistor is to be active. The high level at the CHAIN IN may propagate through the voltage management circuit 902 (i.e., CLAMP HIGH and CLAMP LOW components). At the CHAIN OUT, the signal may be low.

In accordance with various embodiments, the operation of the voltage management circuit 902 may facilitate that when the PMOS transistors are strong, the CHAIN OUT may be low but still far from 0V. When the PMOS transistors are weak, the CHAIN OUT may be low but at a level, which may be close to 0V. Accordingly, the level at P2 gate of the sense amp 904 may be contrariwise to a strength of P2, where the trip point may be shifted by a relatively small amount. As a result, the voltage management circuit 902 may facilitate compensation for a case of P2 being too strong by a small increase in the gate voltage of P2.

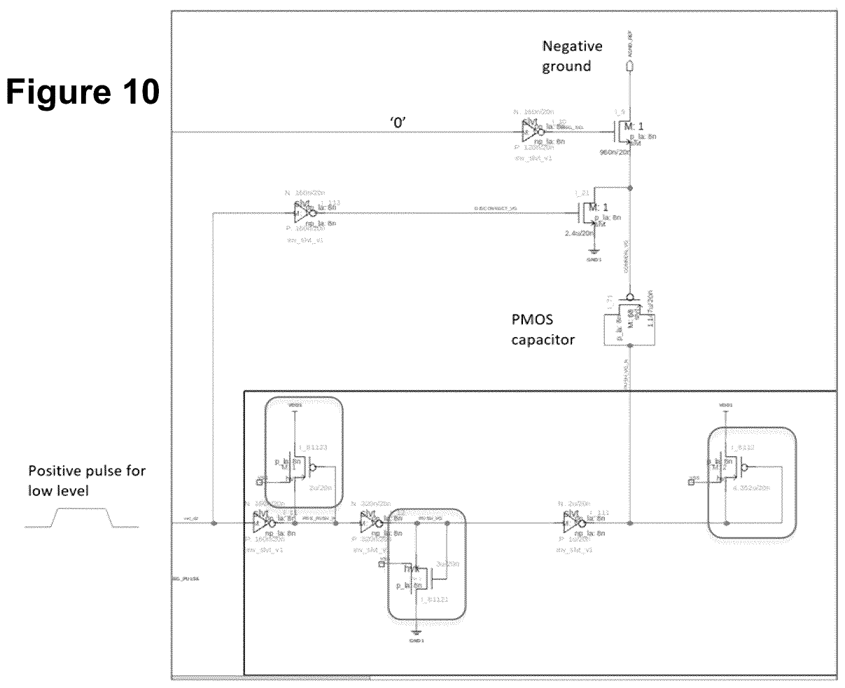

FIG. 10 illustrates utilization of a voltage management circuit in accordance with some additional embodiments. In FIG. 10, a ‘Regular’ Negative ground circuit may be shown. Additional high threshold voltage (Vt) and high width transistors may have their gate-drain electrically coupled. The operation may be based on a different ‘strength’ ratio between a high Vt and a low Vt at different PVTs. The transistor having gate-drain electrically coupled may disturb reaching a full swing at a net, with which it may be electrically coupled. At slow corners (e.g., low voltage, higher Vts), the disturbance may be minor because of the high Vt transistors may be relatively weak. At fast corners (e.g., high voltage, lower Vts), the high Vt transistors may be relatively strong and may reduce the amplitude as a pulse propagates.

It should be appreciated that the voltage management circuit shown in FIG. 10 may be similar to the circuit arrangement 600 (shown in FIG. 6). For example, the circuit arrangement 600 may be considered to be more symbolic. As but one example, in FIG. 6, the circuit arrangement may be illustrated as a passive capacitor, while the voltage management circuit shown in FIG. 10 may include a PMOS transistor configured to function as a capacitor. Accordingly, the claimed subject matter is not limited in these respects.

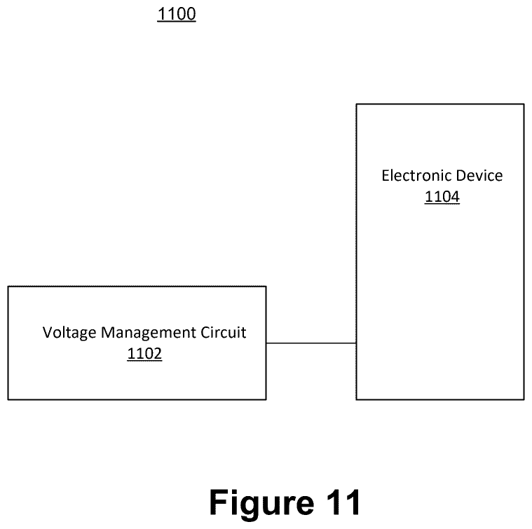

FIG. 11 illustrates a block diagram of system for facilitating management of process corners in accordance with various embodiments. In FIG. 11, an integrated circuit system 1100 may include a voltage management circuit 1102 and an electronic device 1104. As shown in FIG. 11, the voltage management circuit 1102 may be electrically coupled to the electronic device 1104. As described above, the voltage management circuit 1102 may facilitate management of process corners associated with the electronic device 1104 in accordance with various embodiments.

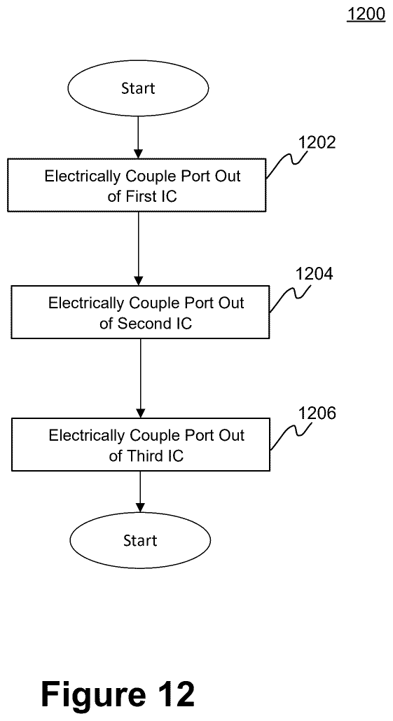

FIG. 12 illustrates an operation flow of the various embodiments disclosed herein. FIG. 12 illustrates an operational flow for facilitating management of a process corner in an integrated circuit in accordance with various embodiments. In some portions of the description, illustrative implementations of the method are described with reference to the elements depicted in FIGS. 1-11. However, the described embodiments are not limited to these depictions.

Additionally, FIG. 12 employs block diagrams to illustrate the example methods detailed therein. These block diagrams may set out various functional block or actions that may be described as processing steps, functional operations, events and/or acts, etc., and may be performed by hardware, software, and/or firmware. Numerous alternatives to the functional blocks detailed may be practiced in various implementations. For example, intervening actions not shown in the figures and/or additional actions not shown in the figures may be employed and/or some of the actions shown in one figure may be operated using techniques discussed with respect to another figure. Additionally, in some examples, the actions shown in these figures may be operated using parallel processing techniques. The above described, and other not described, rearrangements, substitutions, changes, modifications, etc., may be made without departing from the scope of the claimed subject matter.

In some examples, operational flow 1200 may be employed as part of a system for facilitating management of a process corner in an integrated circuit as described herein. Beginning at block 1202 (“Electrically Couple Port Out of First IC”), a port out of a first integrated circuit cell may be electrically coupled to a port in of a second integrated circuit.

Continuing from block 1202 to block 1204 (“Electrically Couple Port Out of Second IC”), a port out of the second integrated circuit cell may be electrically coupled to a port in of a third integrated circuit cell. The first integrated circuit cell may be a clamp high circuit, the second integrated circuit cell may be a clamp low circuit, and the third integrated circuit cell may be a clamp high circuit.

Continuing from block 1204 to 1206 (“Electrically Couple Port Out of Third IC”), a port out of the third integrated circuit cell may be electrically coupled to an electronic device.

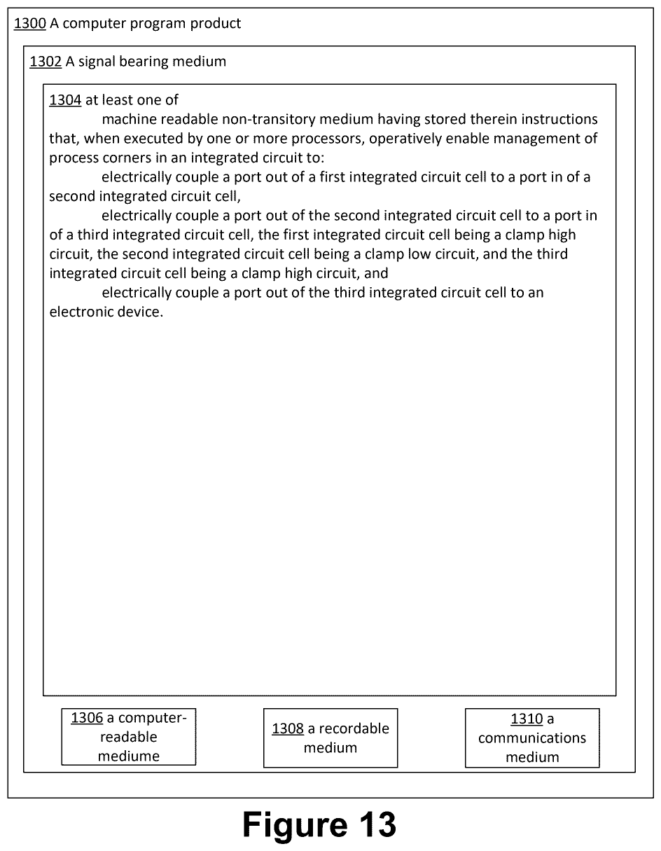

In general, the operational flow described with respect to FIG. 12 and elsewhere herein may be implemented as a computer program product, executable on any suitable computing system, or the like. For example, a computer program product for facilitating passive identification verification and facilitating transactions in a defined area may be provided. Example computer program products may be described with respect to FIG. 13 and elsewhere herein.

FIG. 13 illustrates a computer program product in accordance with various embodiments. FIG. 13 illustrates an example computer program product 1300, arranged in accordance with at least some embodiments described herein. Computer program product 1300 may include machine readable non-transitory medium having stored therein instructions that, when executed, cause the machine to facilitate management of process corners in an integrated circuit according to the processes and methods discussed herein. Computer program product 1300 may include a signal bearing medium 1302. Signal bearing medium 1302 may include one or more machine-readable instructions 1304 which, when executed by one or more processors, may operatively enable a computing device to provide the functionality described herein. In various examples, the devices discussed herein may use some or all of the machine-readable instructions.

In some examples, the machine-readable instructions 1304 may include instructions that enable the computing device to electrically couple a port out of a first integrated circuit cell to a port in of a second integrated circuit cell.

In some examples, the machine-readable instructions 1304 may include instructions that enable the computing device to electrically couple a port out of the second integrated circuit cell to a port in of a third integrated circuit cell, the first integrated circuit cell being a clamp high circuit, the second integrated circuit cell being a clamp low circuit, and the third integrated circuit cell being a clamp high circuit.

In some examples, the machine-readable instructions 1304 may include instructions that enable the computing device to electrically couple a port out of the third integrated circuit cell to an electronic device.

In some implementations, signal bearing medium 1302 may encompass a computer-readable medium 1306, such as, but not limited to, a hard disk drive, a Compact Disc (CD), a Digital Versatile Disk (DVD), a Universal Serial Bus (USB) drive, a digital tape, memory, etc. In some implementations, the signal bearing medium 1302 may encompass a recordable medium 1308, such as, but not limited to, memory, read/write (R/W) CDs, R/W DVDs, etc. In some implementations, the signal bearing medium 1302 may encompass a communications medium 1310, such as, but not limited to, a digital and/or an analog communication medium (e.g., a fiber optic cable, a waveguide, a wired communication link, a wireless communication link, etc.). In some examples, the signal bearing medium 1302 may encompass a machine readable non-transitory medium.

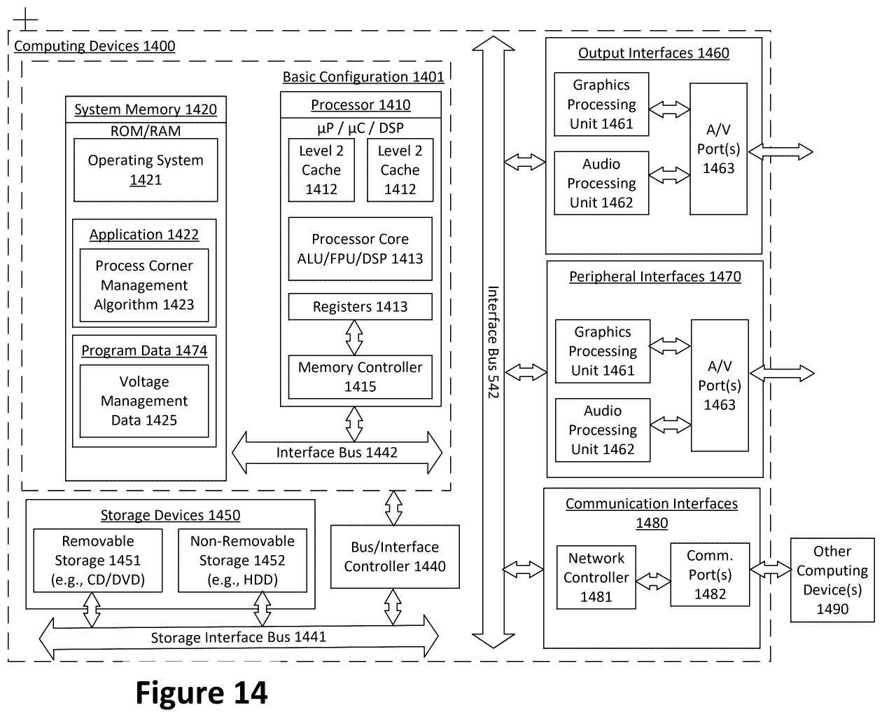

In general, the methods described with respect to FIG. 13 and elsewhere herein may be implemented in any suitable computing system. Example systems may be described with respect to FIG. 14 and elsewhere herein. In general, the system may be configured to facilitate management of process corners in an integrated in accordance with various embodiments.

FIG. 14 illustrates an example computer device. FIG. 14 is a block diagram illustrating an example computing device 1400, such as might be embodied by a person skilled in the art, which is arranged in accordance with at least some embodiments of the present disclosure. In one example configuration, computing device 1400 may include one or more processors 1410 and system memory 1420. A memory bus 1430 may be used for communicating between the processor 1410 and the system memory 1420.

Depending on the desired configuration, processor 1410 may be of any type including but not limited to a microprocessor (μP), a microcontroller (μC), a digital signal processor (DSP), or any combination thereof. Processor 1410 may include one or more levels of caching, such as a level one cache 1411 and a level two cache 1412, a processor core 1413, and registers 1414. The processor core 1413 may include an arithmetic logic unit (ALU), a floating-point unit (FPU), a digital signal processing core (DSP Core), or any combination thereof. A memory controller 1415 may also be used with the processor 1410, or in some implementations the memory controller 1415 may be an internal part of the processor 1410.

Depending on the desired configuration, the system memory 1420 may be of any type including but not limited to volatile memory (such as RAM), non-volatile memory (such as ROM, flash memory, etc.) or any combination thereof. System memory 1420 may include an operating system 1421, one or more applications 1422, and program data 1424. Application 1422 may include process corner management algorithm 1423 that is arranged to perform the functions as described herein including the functional blocks and/or actions described. Program Data 1424 may include, among other information described, voltage management data 1425 for use with the process corner management algorithm 1423. In some example embodiments, application 1422 may be arranged to operate with program data 1424 on an operating system 1421 such that implementations of the management of a process corner in an integrated circuit may be provided as described herein. For example, apparatus described in the present disclosure may comprise all or a portion of computing device 1400 and be capable of performing all or a portion of application 1422 such that facilitating management of a process corner in an integrated circuit as described herein. This described basic configuration is illustrated in FIG. 14 by those components within dashed line 1401.

Computing device 1400 may have additional features or functionality, and additional interfaces to facilitate communications between the basic configuration 1401 and any required devices and interfaces. For example, a bus/interface controller 1440 may be used to facilitate communications between the basic configuration 1401 and one or more data storage devices 1450 via a storage interface bus 1441. The data storage devices 1450 may be removable storage devices 1451, non-removable storage devices 1452, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 1420, removable storage 1451 and non-removable storage 1452 are all examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information, and which may be accessed by computing device 1400. Any such computer storage media may be part of device 1400.

Computing device 1400 may also include an interface bus 1442 for facilitating communication from various interface devices (e.g., output interfaces, peripheral interfaces, and communication interfaces) to the basic configuration 1401 via the bus/interface controller 1440. Example output interfaces 1460 may include a graphics processing unit 1461 and an audio processing unit 1462, which may be configured to communicate to various external devices such as a display or speakers via one or more A/V ports 1463. Example peripheral interfaces 1460 may include a serial interface controller 1471 or a parallel interface controller 1472, which may be configured to communicate with external devices such as input devices (e.g., keyboard, mouse, pen, voice input device, touch input device, etc.) or other peripheral devices (e.g., printer, scanner, etc.) via one or more I/O ports 1473. An example communication interface 1480 includes a network controller 1481, which may be arranged to facilitate communications with one or more other computing devices 1490 over a network communication via one or more communication ports 1482. A communication connection is one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), infrared (IR) and other wireless media. The term computer readable media as used herein may include both storage media and communication media.

Computing device 1400 may be implemented as a portion of a small-form factor portable (or mobile) electronic device such as a cell phone, a personal data assistant (PDA), a personal media player device, a wireless web-watch device, a personal headset device, an application specific device, or a hybrid device that includes any of the above functions. Computing device 1400 may also be implemented as a personal computer including both laptop computer and non-laptop computer configurations. In addition, computing device 1400 may be implemented as part of a wireless base station or other wireless system or device.

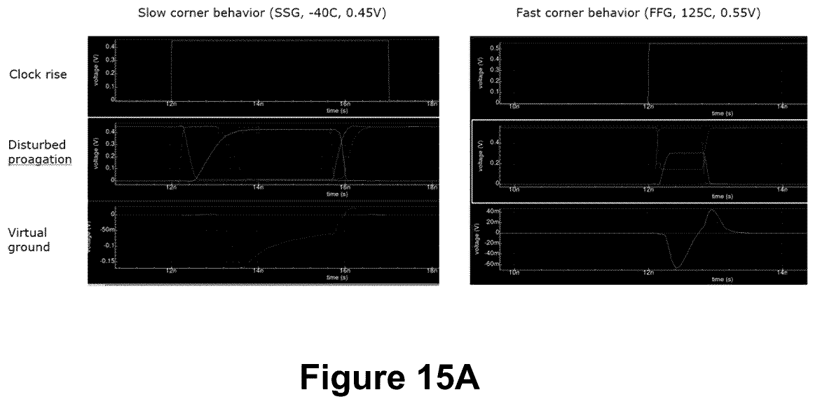

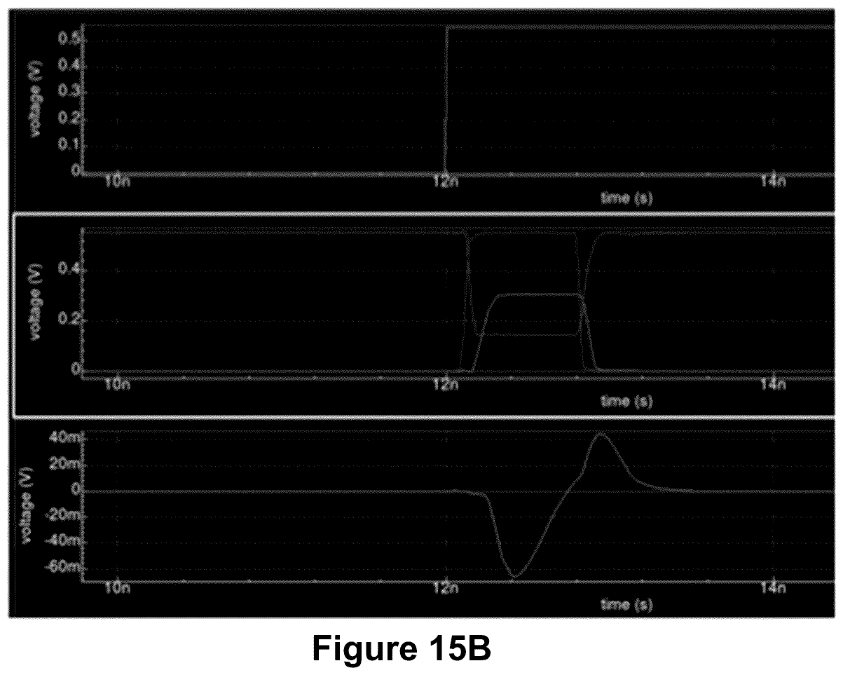

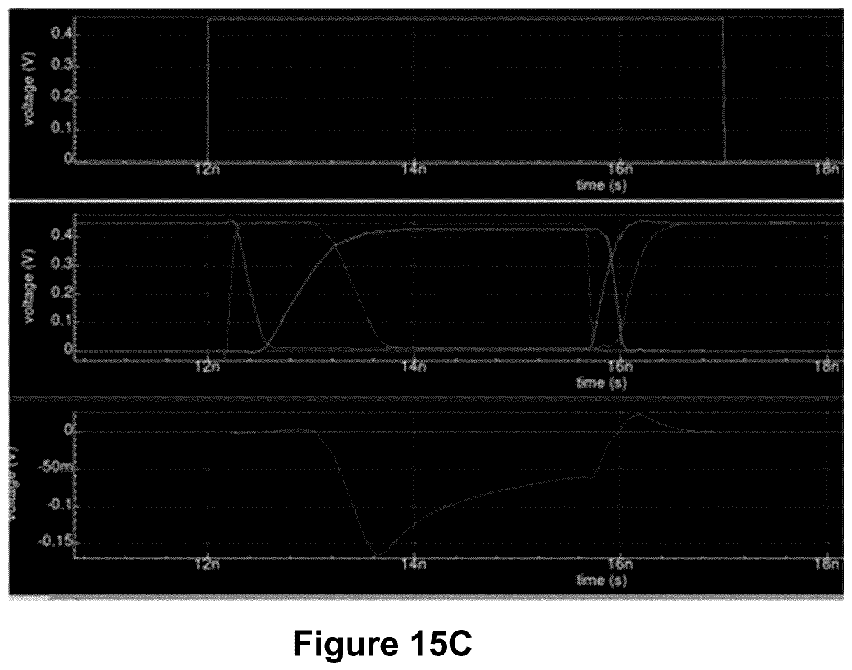

FIGS. 15A-15C illustrate wave forms associated with some embodiments.

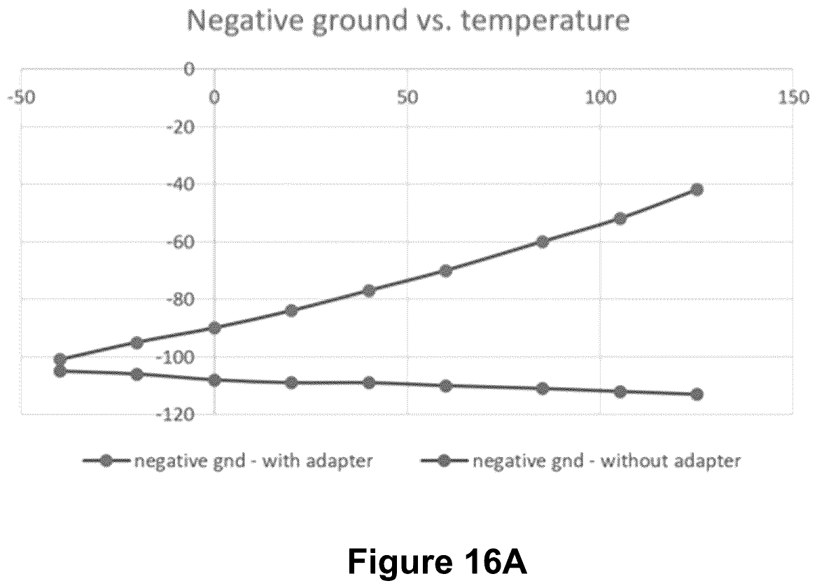

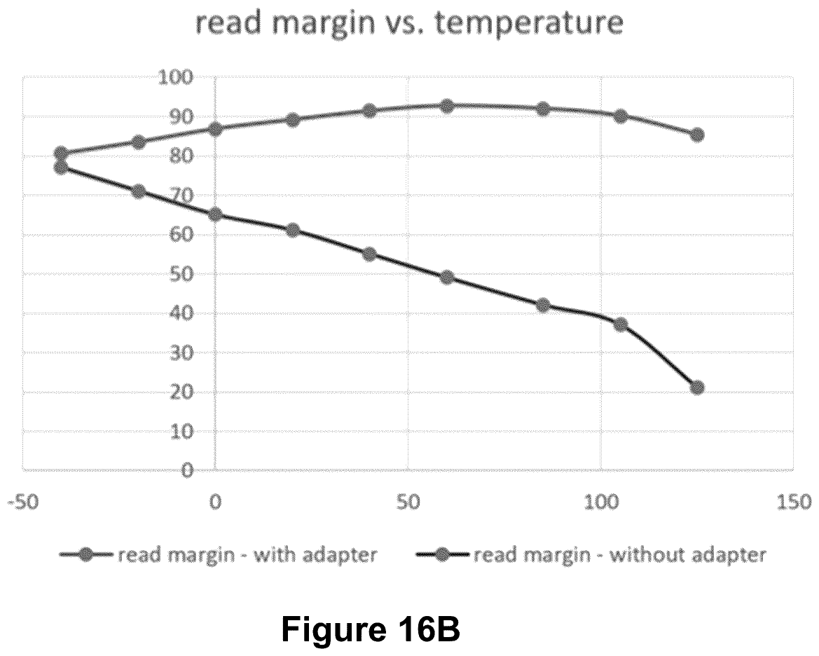

FIGS. 16A-16B illustrate some circuit behavior associated with some embodiments.

Some embodiments may be utilized to facilitate pulse level reduction, which may be applicable to a variety of types of boost. Some embodiments may be utilized to facilitate 0/1 signal detection of high speed corners and/or low speed corners. Undefined intermediate states may be resolved (e.g., standard synchronization).

It should be appreciated after review of this disclosure that it is contemplated within the scope and spirit of the present disclosure that the claimed subject matter may include a wide variety of integrated circuit devices. Accordingly, the claimed subject matter is not limited in these respects.

Some portions of the foregoing detailed description are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is here, and generally, considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussion utilizing terms such as “processing,” “computing,” “calculating,” “determining” or the like refer to actions or processes of a computing device that manipulates or transforms data represented as physical electronic or magnetic quantities within memories, registers, or other information storage devices, transmission devices, or display devices of the computing device.

Claimed subject matter is not limited in scope to the particular implementations described herein. For example, some implementations may be in hardware, such as those employed to operate on a device or combination of devices, for example, whereas other implementations may be in software and/or firmware. Likewise, although claimed subject matter is not limited in scope in this respect, some implementations may include one or more articles, such as a signal bearing medium, a storage medium and/or storage media. This storage media, such as CD-ROMs, computer disks, flash memory, or the like, for example, may have instructions stored thereon that, when executed by a computing device such as a computing system, computing platform, or other system, for example, may result in execution of a processor in accordance with claimed subject matter, such as one of the implementations previously described, for example. As one possibility, a computing device may include one or more processing units or processors, one or more input/output devices, such as a display, a keyboard and/or a mouse, and one or more memories, such as static random-access memory, dynamic random-access memory, flash memory, and/or a hard drive.

There is little distinction left between hardware and software implementations of aspects of systems; the use of hardware or software is generally (but not always, in that in certain contexts the choice between hardware and software can become significant) a design choice representing cost vs. efficiency tradeoffs. There are various vehicles by which processes and/or systems and/or other technologies described herein can be affected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skilled in the art in light of this disclosure. In addition, those skilled in the art will appreciate that the mechanisms of the subject matter described herein are capable of being distributed as a product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a flexible disk, a hard disk drive (HDD), a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a semiconductor integrated circuit system via a reasonable amount of experimentation. Those having skill in the art will recognize that a typical semiconductor integrated circuit system generally may be included in one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical semiconductor integrated circuit system may be implemented utilizing any suitable commercially available components, such as those typically found in computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Reference in the specification to “an implementation,” “one implementation,” “some implementations,” or “other implementations” may mean that a particular feature, structure, or characteristic described in connection with one or more implementations may be included in at least some implementations, but not necessarily in all implementations. The various appearances of “an implementation,” “one implementation,” or “some implementations” in the preceding description are not necessarily all referring to the same implementations.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter is not limited to the particular examples disclosed, but that such claimed subject matter also may include all implementations falling within the scope of the appended claims, and equivalents thereof.

1. An integrated circuit system for management of process corners comprising:
an electronic device, the electronic device having one or more transistors; and
a voltage management circuit, the voltage management circuit electrically coupled to the electronic device and having one or more transistors configured to manage a behavior of a voltage of the electronic device.

2. The integrated circuit system of claim 1, wherein the voltage management circuit comprises at least one of a clamp high circuit and a clamp low circuit.

3. The integrated circuit system of claim 2, wherein the clamp high circuit comprises a low VT inverter and a high VT PMOS.

4. The integrated circuit system of claim 3, wherein the high VT PMOS comprises the high VT PMOS having a gate electrically coupled to a drain and a source being electrically coupled to a VDD.

5. The integrated circuit system of claim 2, wherein the clamp low circuit comprises a low VT inverter and a high VT NMOS.

6. The integrated circuit system of claim 5, wherein the high VT NMOS comprises the high VT NMOS having a gate electrically coupled to a drain and a source being electrically coupled to a ground.

7. The integrated circuit system of claim 1, wherein the voltage management circuit comprises a first clamp high circuit electrically coupled to a clamp low circuit and the low clamp circuit being electrically coupled to a second clamp high circuit.

8. The integrated circuit system of claim 1, wherein the electronic device comprises a memory.

9. The integrated circuit system of claim 8, wherein the memory comprises an SRAM memory.

10. The integrated circuit system of claim 1, wherein the electronic device comprises a sense amplifier.

11. The integrated circuit system of claim 10, wherein the sense amplifier comprises a single ended sense amplifier included in an SRAM.

12. A method of managing a process corner in an integrated circuit, the method comprising:
electrically coupling a port out of a first integrated circuit cell to a port in of a second integrated circuit cell;
electrically coupling a port out of the second integrated circuit cell to a port in of a third integrated circuit cell, the first integrated circuit cell being a clamp high circuit, the second integrated circuit cell being a clamp low circuit, and the third integrated circuit cell being a clamp high circuit; and
electrically coupling a port out of the third integrated circuit cell to an electronic device.

13. The method of claim 12 further comprising electrically coupling a fourth integrated circuit cell to the port out of the third integrated circuit cell, the fourth integrated circuit cell being a clamp low circuit and a port out of the fourth integrated circuit cell being electrically coupled to the electronic device.

14. The method of claim 12, wherein electrically coupling the port out of the third integrated circuit cell comprises electrically coupling the port out of the third integrated circuit cell to a reference column included in a memory.

15. The method of claim 14, wherein electrically coupling the port out of the third integrated circuit cell to the reference column comprises electrically coupling the port out of the third integrated circuit cell to the reference column included in an SRAM.

16. The method of claim 12, wherein electrically coupling the port out of the third integrated circuit cell comprises electrically coupling the port out of the third integrated circuit cell to a sense amplifier, the sense amplifier being included in a memory.

17. The method of claim 16, wherein electrically coupling the port out of the third integrated circuit cell to the sense amplifier comprises electrically coupling the port out of the third integrated circuit cell to the sense amplifier included in the SRAM having 8T bitcell.
